(19) United States
(12) Patent Application Publication
(10) Pub. No.: US 2020/0243537 A1
(43) Pub. Date: Jul. 30, 2020

(54) FORMATION OF A TRENCH USING A POLYMERIZING RADICAL MATERIAL

(71) Applicant: Micron Technology, Inc., Boise, ID (US)

(72) Inventors: Yan Li, Boise, ID (US); Song Guo, Boise, ID (US); Mohd Kamran Akhtar, Boise, ID (US); Alex J. Schrinsky, Boise, ID (US)

(21) Appl. No.: 16/259,634

(22) Filed: Jan. 28, 2019

(51) Int. Cl. H01L 27/108; H01G 4/08; H01G 4/012; H01G 4/008

(52) U.S. Cl. CPC H01L 27/10861; H01L 27/10829; H01G 4/08; H01G 4/008; H01L 27/10852; H01L 27/10894; H01G 4/012

(57) ABSTRACT

Methods, apparatuses, and systems related to forming a trench using a polymerizing radical material. An example method includes depositing a polymerizing radical material in a number of trenches formed over a substrate. The method further includes etching a portion of the deposited polymerizing radical material from the number of trenches. The example method further includes selectively etching into one of the number of trenches below the deposited polymerizing radical material. The one of the number of trenches is narrower than another of the number of trenches.

### TECHNICAL FIELD

The present disclosure relates generally to semiconductor devices and methods, and more particularly to formation of a trench using a polymerizing radical material.

### BACKGROUND

Memory devices are typically provided as internal, semiconductor, integrated circuits in computers or other electronic devices. There are many different types of memory, including random-access memory (RAM), read only memory (ROM), dynamic random access memory (DRAM), static random access memory (SRAM), synchronous dynamic random access memory (SDRAM), ferroelectric random access memory (FeRAM), magnetic random access memory (MRAM), resistive random access memory (ReRAM), and flash memory, among others. Some types of memory devices may be non-volatile memory (e.g., ReRAM) and may be used for a wide range of electronic applications in need of high memory densities, high reliability, and low power consumption. Volatile memory cells (e.g., DRAM cells) require power to retain their stored data state (e.g., via a refresh process), as opposed to non-volatile memory cells (e.g., flash memory cells), which retain their stored state in the absence of power. However, various volatile memory cells, such as DRAM cells may be operated (e.g., programmed, read, erased, etc.) faster than various non-volatile memory cells, such as flash memory cells.

### BRIEF DESCRIPTION OF THE DRAWINGS

FIG. 1 illustrates a cross-section view of a portion of an example memory device in accordance with of the present disclosure.

FIGS. 2-4 illustrate cross-sectional views of a portion of an example memory device at stages of an example fabrication sequence for formation of a trench using a polymerizing radical material in accordance with a number of embodiments of the present disclosure.

FIGS. 5-6 are flow diagrams of example methods for fabrication sequence for formation of a trench using a polymerizing radical material in accordance with a number of embodiments of the present disclosure.

FIG. 7 is a functional block diagram of a computing system including at least one memory system in accordance with one or more embodiments of the present disclosure.

### DETAILED DESCRIPTION

Various types of memory devices (e.g., those that include volatile or non-volatile memory cells) may include rectilinear trenches and/or round, square, oblong, etc., cavities that may be formed into a sidewall structural material as openings. Such openings may contain, or be associated with, various materials that contribute to data access, storage, and/or processing, or to various support structures, on the memory device. As an example, capacitor material may be deposited into these openings to provide the data access, storage, and/or processing.

A fin height of a passing word line (PWL) and an active word line (AWL) can affect the impact of a row hammer (RH) and/or drive current performance of a memory device word line. An RH can refer to a leakage of charge of memory cells that interacts electrically between the memory cells and may change the contents of nearby rows of memory cells that were not intended to be addressed in the original memory access. The fin height of the AWL being deeper than a PWL can improve results of an RH and/or drive current performance. However, in some examples, an opening associated with an AWL can have a narrower width than an opening associated with a PWL. This can create difficulties in forming an AWL deeper than a PWL in that the wider opening of the PWL may tend to etch deeper than an AWL. A series of depositions and etches, as described below, can avoid this difficulty and result in an opening of an AWL being deeper than an opening of a PWL.

The present disclosure includes methods, apparatuses, and systems related to forming a trench using a polymerizing radical material. An example of a method described herein includes deposition of a polymerizing radical material into openings of trenches. The example method includes etching the deposited polymerizing radical material to remove the polymerizing radical material from the AWL trenches down to the silicate material below. The example method includes etching into the silicate material of the AWL trenches while avoiding etching into the silicate material of the PWL trenches.

In the following detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure. As used herein, “a number of” something can refer to one or more such things. For example, a number of capacitors can refer to at least one capacitor.

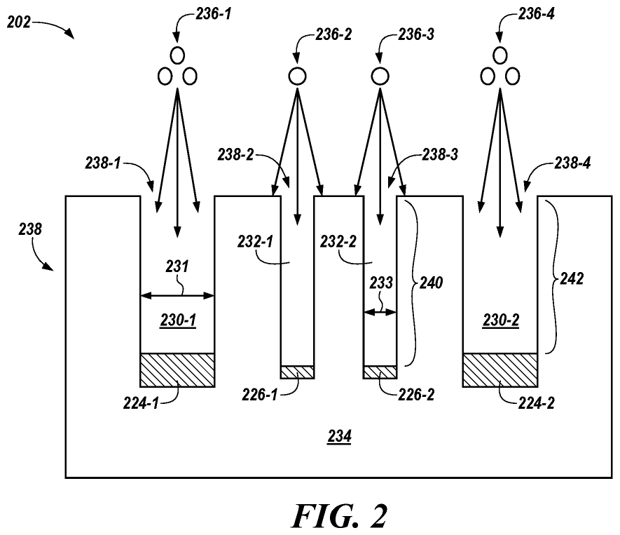

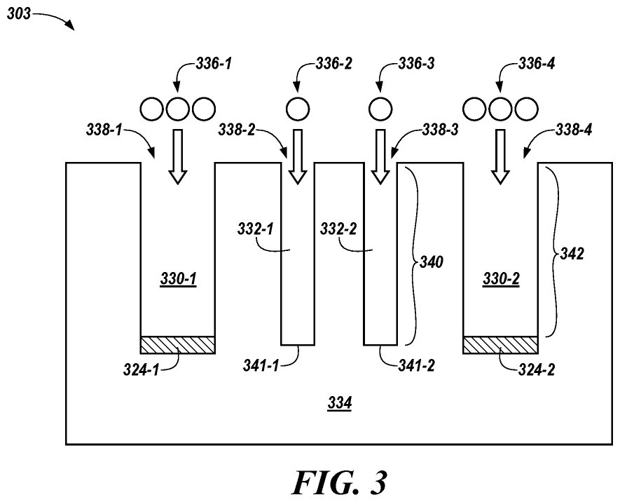

The figures herein follow a numbering convention in which the first digit or digits correspond to the figure number of the drawing and the remaining digits identify an element or component in the drawing. Similar elements or components between different figures may be identified by the use of similar digits. For example, reference numeral 234 may reference element “34” in FIG. 2, and a similar element may be referenced as 334 in FIG. 3. In some instances, a plurality of similar, but functionally and/or structurally distinguishable, elements or components in the same figure or in different figures may be referenced sequentially with the same element number (e.g., 236-1, 236-2, 236-3, 236-4 in FIG. 2).

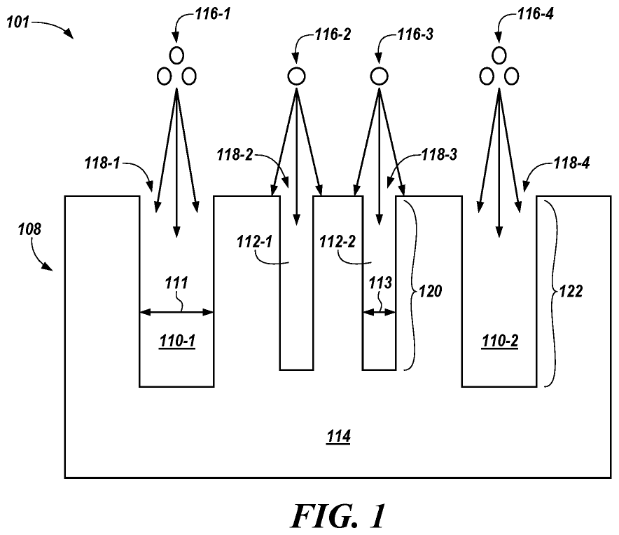

FIG. 1 illustrates a cross-sectional view of a portion of an example memory device 101 at a particular stage in an example semiconductor fabrication sequence for forming a trench using a polymerizing radical material in accordance with a number of embodiments of the present disclosure. The example memory device 101 can include a substrate portion 114. While not illustrated, the substrate portion 114 can include a number of additional materials and/or layers, such as nitride material, silicate material, etc. The example memory device 101 can include a first set of trenches 110-1, 110-2 (hereinafter referred to collectively as first set of trenches 110) and a second set of trenches 112-1, 112-2 (hereinafter referred to collectively as second set of trenches 112). In some examples, the first set of trenches 110 can be passing word line trenches. In some examples, the second set of trenches 112 can be active word line trenches. As is illustrated, a width 111 of the first set of trenches 110 can be wider than a width 113 of the second set of trenches 112.

As illustrated in FIG. 1, the first set of trenches 110-1, 110-2 can each include openings 118-1, 118-4, respectively and the second set of trenches 112-1, 112-2 can each include openings 118-2, 118-3, respectively. In some examples, etching material 116-1, 116-2, 116-3, 116-4 can be directed into the openings 118-1, 118-2, 118-3, 118-4, respectively, to etch material at a bottom of the first set of trenches 110-1, 110-2 and the second set of trenches 112-1, 112-2.

However, due to the differences in width of the first set of trenches 110 and the second set of trenches 112, the first set of trenches will be etched deeper, as illustrated in FIG. 1. As an example, a depth 122 of the first set of trenches 110 is deeper than a depth 120 of the second set of tranches. This can be due to it being more difficult to reach the bottom of narrower spaces (e.g., the narrower trenches of the second set of trenches 112) due to a diffusion controlled transport process that drives depletion of reactants and removal of etch by-products in narrow features. Further, it can be more difficult for reactive radicals used in the etching process to reach the bottom of narrower spaces due to divergent ion flux, collisions in sheath, and sidewall charging. This differential in etching due to varying widths can be referred to as micro-loading. As will be described further below, this can be avoided by performing a number of etching and deposition methods.

FIG. 2 illustrates a cross-sectional view of a portion of an example memory device 202 at a particular stage in an example semiconductor fabrication sequence for forming a trench using a polymerizing radical material in accordance with a number of embodiments of the present disclosure. The example memory device 202 can include a substrate portion 234. While not illustrated, the substrate portion 234 can include a number of additional materials and/or layers, such as a nitride material, a silicate material, etc.

The nitride material can include at least one of boron nitride (BN), silicon nitride (SiN_{X}, Si₃N₄), aluminum nitride (AlN), gallium nitride (GN), tantalum nitride (TaN, Ta2N), titanium nitride (TiN, Ti₂N), and tungsten nitride (WN, W₂N, WN₂), among other possibilities, for formation of the nitride material. The silicate material can include at least one of borophosphosilicate glass (BPSG), borosilicate glass (BSG), phosphosilicate glass (PSG), or TEOS (tetraethyl orthosilicate (Si(OC₂H₅)₄, which may be formed as an ethyl ester of orthosilicic acid (Si(OH)₄)), among other possibilities.

The example memory device 202 can include a first set of trenches 230-1, 230-2 (hereinafter referred to collectively as first set of trenches 230) and a second set of trenches 232-1, 232-2 (hereinafter referred to collectively as second set of trenches 232). In some examples, the first set of trenches 230 can be passing word line trenches. In some examples, the second set of trenches 232 can be active word line trenches. As is illustrated, a width 231 of the first set of trenches 230 can be wider than a width 2333 of the second set of trenches 232.

As illustrated in FIG. 2, the first set of trenches 230-1, 230-2 can each include openings 238-1, 238-4, respectively and the second set of trenches 232-1, 232-2 can each include openings 238-2, 238-3, respectively. In some examples, a polymerizing radical material 236-1, 236-2, 236-3, 236-4 (hereinafter referred to collectively as polymerizing radical material 236) can be directed into the openings 238-1, 238-2, 238-3, 238-4, respectively, during deposition to form the polymerizing radical material 236 at a bottom of the first set of trenches 230-1, 230-2 and the second set of trenches 232-1, 232-2.

As an example, the polymerizing radical material 236-1 and 236-4 can be directed into openings 238-1 and 238-4, respectively, resulting in a formation of polymerizing radical material 224-1 and 224-2, respectively, in trenches 230-1 and 230-2, respectively. Likewise, the polymerizing radical material 236-2 and 236-3 can be directed into openings 238-2 and 238-3, respectively, resulting in a formation of polymerizing radical material 226-1 and 226-2, respectively, in trenches 232-1 and 232-2, respectively. The polymerizing radical material 236 can include one or both of CF₄ and CH₂F₂, as an example.

The polymerizing radical material 236 can be deposited with a low bias power to form a deposition layer. In one example, low bias power can refer to a volt bias voltage of 100 to 200 volts. In one example, low bias power can refer to a volt bias voltage of 160 volts. This low bias power can lead to a low radical ion energy, which can be used to deposit more polymer in wider openings. As an example, as the width 231 of the trench 230-1 (and also trench 230-2) is wider than the width 233 of the trench 232-2 (and also trench 232-1), the polymerizing radical material 236 accumulates a greater amount of polymerizing radical material 224 in the first set of trenches 230 than the second set of trenches 232. This can lead to a depth 242 of the first set of trenches 230 being less than a depth 240 of the second set of trenches 232.

FIG. 3 illustrates a cross-sectional view of a portion of an example memory device 303 at a particular stage in an example semiconductor fabrication sequence for forming a trench using a polymerizing radical material in accordance with a number of embodiments of the present disclosure. As an example, memory device 303 illustrated in FIG. 3 is memory device 202 but at a subsequent stage of formation of the trench. The example memory device 303 can include a substrate portion 334. While not illustrated, the substrate portion 334 can include a number of additional materials and/or layers, such as a nitride material, a silicate material, etc.

As was described in association with FIG. 3, the nitride material can include at least one of boron nitride (BN), silicon nitride (SiN_{X}, Si₃N₄), aluminum nitride (AlN), gallium nitride (GN), tantalum nitride (TaN, Ta₂N), titanium nitride (TiN, Ti₂N), and tungsten nitride (WN, W₂N, WN₂), among other possibilities, for formation of the nitride material. The silicate material can include at least one of borophosphosilicate glass (BPSG), borosilicate glass (BSG), phosphosilicate glass (PSG), or TEOS (tetraethyl orthosilicate (Si(OC₂H₅)₄, which may be formed as an ethyl ester of orthosilicic acid (Si(OH)₄)), among other possibilities. In at least some embodiments, the nitride material may be formed from a nitride material selected for dielectric or resistance properties. For example, one or more dielectric and/or resistor nitrides may be selected from BN, SiN_{X}, Si₃N₄, AlN, GN, TaN, Ta₂N, TiN, Ti₂N), and WN, W₂N, WN₂, among other possibilities, for formation of the nitride material.

The example memory device 303 can include a first set of trenches 330-1, 330-2 (hereinafter referred to collectively as first set of trenches 330) and a second set of trenches 332-1, 332-2 (hereinafter referred to collectively as second set of trenches 332). In some examples, the first set of trenches 330 can be passing word line trenches. In some examples, the second set of trenches 332 can be active word line trenches.

As illustrated in FIG. 3, the first set of trenches 330-1, 330-2 can each include openings 338-1, 338-4, respectively and the second set of trenches 332-1, 332-2 can each include openings 338-2, 338-3, respectively. In some examples, a reactive radical material 336-1, 336-2, 336-3, 336-4 (hereinafter referred to collectively as reactive radical material 336) can be directed into the openings 338-1, 338-2, 338-3, 338-4, respectively, during etching to remove the polymerizing radical material 324 (and 226 shown in FIG. 2) at a bottom of the first and the second set of trenches 330/332.

The polymerizing radical material (224/226) may be removed with (via application of) a solvent that is selective for removing (e.g., dissolving) the polymerizing radical material from the memory device while not removing (e.g., leaving) other materials such that those materials remain in the memory device. Such a selective solvent may be selected from water (H₂O), methanol (CH₃OH), ethanol (C₂H₅OH), isomers of propanol (C₃H₇OH) such as n-propanol and isopropanol, n-butanol (C₄H₉OH), among other possible alcohols, and sulfuric acid (H₂SO₄), and combinations thereof, among other possibilities. This removal may leave empty spaces (e.g., voids) in the structure of the memory device that expose a portion of the trenches.

The reactive radical material 336 can be delivered with a high bias power to clear the polymerizing radical material 324 (and 226 shown in FIG. 2) deposited, as was described in association with FIG. 2. In one example, high bias power can refer to a range of volt bias voltage of 800 to 1600 volts. In one example, high bias power can refer to a volt bias voltage of 1200 volts. The high bias power can lead to a high radical ion energy which can increase an amount of etching of the polymerizing radical material 324 (and 226 shown in FIG. 2) in a narrower second set of trenches 332. In this way, the polymerizing radical material of the second set of trenches 332 can be removed at a higher rate and at an earlier period in time than the polymerizing radical material 324 of the first set of trenches 330. This can expose the portion of the second set of trenches 332 beneath the polymerizing radical material (not shown as it has been removed) before the portion of the first set of trenches 330 beneath the polymerizing radical material 324.

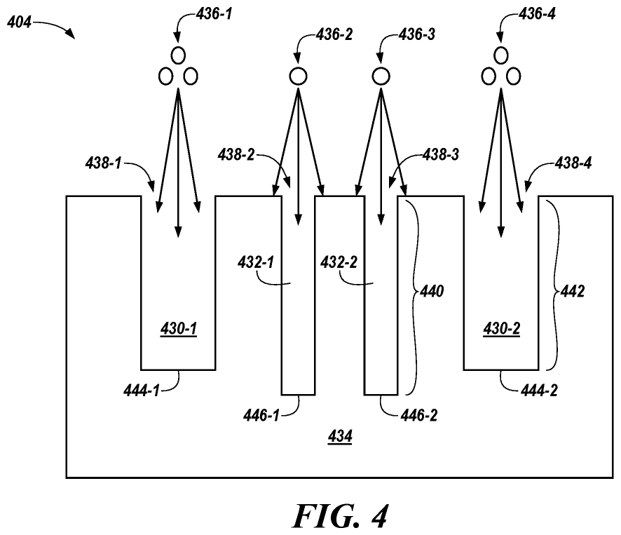

FIG. 4 illustrates a cross-sectional view of a portion of an example memory device 404 at a particular stage in an example semiconductor fabrication sequence for forming a trench using a polymerizing radical material in accordance with a number of embodiments of the present disclosure. As an example, memory device 404 illustrated in FIG. 4 is memory devices 202 and 303 in FIGS. 2-3 but at a subsequent stage to the deposition and etching described in association with FIGS. 2-3 for the formation of the trench. The example memory device 404 can include a substrate portion 434. While not illustrated, the substrate portion 434 can include a number of additional materials and/or layers, such as a nitride material, a silicate material, etc., as described with FIGS. 2-3.

The example memory device 404 includes the first set of trenches 430-1, 430-2 (hereinafter referred to collectively as first set of trenches 430) and the second set of trenches 432-1, 432-2 (hereinafter referred to collectively as second set of trenches 432). In some examples, the first set of trenches 430 can be passing word line trenches. In some examples, the second set of trenches 432 can be active word line trenches.

As illustrated in FIG. 4, the first set of trenches 430-1, 430-2 can each include openings 438-1, 438-4, respectively and the second set of trenches 432-1, 432-2 can each include openings 438-2, 438-3, respectively. In some examples, an etching material 436-1, 436-2, 436-3, 436-4 (hereinafter referred to collectively as etching material 436) can be directed into the openings 438-1, 438-2, 438-3, 438-4, respectively, during etching to remove the polymerizing radical material (such as removal of 324-1 and 324-2 in FIG. 3) in the first set of trenches 330 and a silicate material 446-1, 446-2 that is exposed in the second set of trenches 432. The etching material can include at least one of chlorine (Cl), hydrogen bromide (HBr), tetrafluoromethane (CF₄), difluoromethane (CH₂F₂), and argon (Ar), where Ar is a carrier gas that directs the etch radical into the etch front. The etching material 436 used can etch faster into silicate material than polymer (e.g., the polymerizing radical material), resulting in the polymerizing radical material (324-1 and 324-2 shown in FIG. 3) of the first set of trenches being etched more slowly than the silicate material 446-1 and 446-2 (and 341-1 and 341-2 in FIG. 3).

The silicate material may, in a number of embodiments, have been formed from a borophosphosilicate glass (BPSG). The BPSG may include a silicon compound doped with various concentrations and/or ratios of a boron compound and a phosphorus compound. The silicon compound may be silicon dioxide (SiO₂), which may be formed by oxidation of silane (SiH₄), among other possibilities. The boron compound may be diboron trioxide (B₂O₃), which may be formed by oxidation of diborane (B₂H₆), among other possibilities. The phosphorus compound may be diphosphorus pentoxide (P₂O₅), which may be formed by oxidation of phosphine (PH₃), among other possibilities. The silicon, boron, and phosphorus compounds of the BPSG may include various isotopes of silicon, boron, and phosphorus, as determined to be appropriate for functionality, formation, and/or removal of the silicate material, as described herein. In addition, the silicate material, in a number of embodiments, be formed from tetraethyl orthosilicate (Si(OC₂H₅)₄), which is also referred to as TEOS. TEOS may be formed as an ethyl ester of orthosilicic acid (Si(OH)₄), among other possibilities.

At a conclusion of the etching illustrated in FIG. 4, the trenches can be exposed to depth locations 444-1 and 444-2 for the first set of trenches 430 and depth locations 446-1 and 446-2 for the second set of trenches. In this way, the second set of trenches 432 can be etched to a depth 440 that is deeper than a depth 442 of the first set of trenches 430.

The deposition and etching process described in association with FIGS. 2-4 can be repeated a number of times in order to etch the second set of trenches 432 to a depth deeper than the first set of trenches 430 until the depth of the second set of trenches 432 reaches a threshold depth. In this way, the effects of micro-loading (an effect where wider trenches are etched to a deeper depth) can be avoided and a trench that is narrower in width can be etched deeper than a trench that is wider.

Subsequent to the formation process described in association with FIGS. 2-4, a capacitor material may be deposited into the openings 438. In addition, a first dielectric material can be formed on the surface of the substrate 434 and sidewalls of the trenches 430/432 surrounding the capacitor material. Further, a second dielectric material may be formed (e.g., deposited) on the first dielectric material. A buffer material may be formed on the second dielectric material and may be formed around and between a number of capacitors (e.g., capacitors formed in the trenches 430/432) as electrical insulation. The dielectric materials and the buffer material may be formed from any respective dielectric materials, conductive materials, and resistive materials and to any width (e.g., thickness) usable in association with formation of an operable capacitor for a semiconductor device.

Formation of the capacitors as described may be utilized in fabrication of a memory device that includes at least one memory cell. Such a memory cell may include at least one such capacitor, as a data storage element. The memory cell also may include at least one access device (e.g., transistor) (not shown) that is, or may be, coupled to the at least one capacitor.

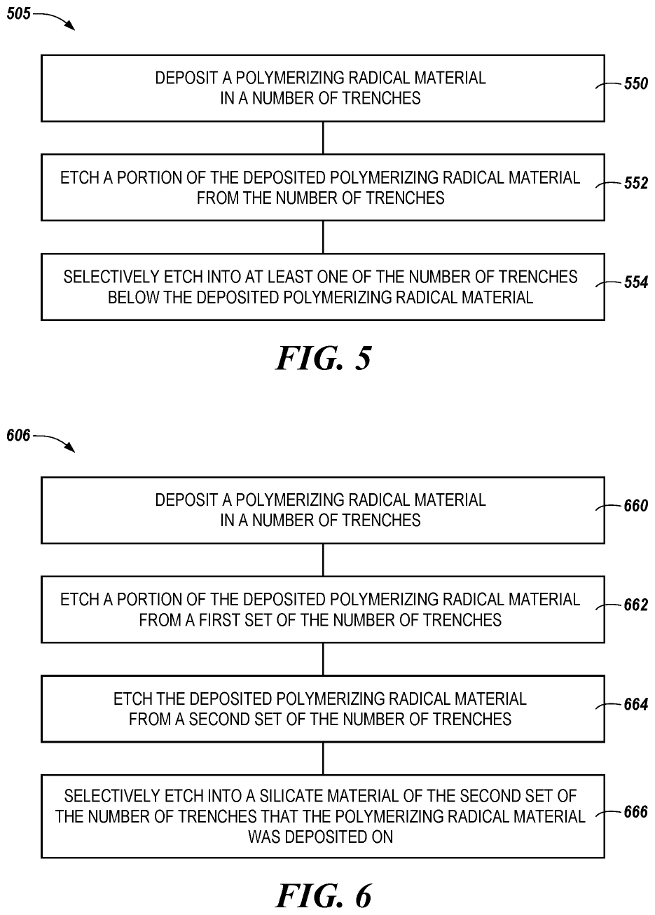

FIG. 5 is a flow diagram of an example method 505 for formation of a trench by using a polymerizing radical material in accordance with a number of embodiments of the present disclosure. Unless explicitly stated, elements of methods described herein are not constrained to a particular order or sequence. Additionally, a number of the method embodiments, or elements thereof, described herein may be performed at the same, or at substantially the same, point in time.

At block 550, the method 505 may include depositing a polymerizing radical material in a number of trenches. In some examples, a polymerizing radical material (such as polymerizing radical material 236-1, 236-2, 236-3, 236-4 in FIG. 2) can be directed into openings of trenches to form the polymerizing radical material at a bottom of the trenches. The trenches may have differing width. A wider trench may receive more polymerizing radical material than a narrower trench. The polymerizing radical material can include one or both of CF₄ and CH₂F₂, as an example.

The polymerizing radical material can be deposited with a low bias power to form a deposition layer. This low bias power can lead to a low radical ion energy, which can be used to deposit more polymer in wider openings. As an example, a trench with a wider width can accumulate a greater amount of polymerizing radical material than a trench with a narrower width.

At block 552, the method 505 can include etching a portion of the deposited polymerizing radical material from the number of trenches. In some examples, a reactive radical material (such as reactive radical material 336-1, 336-2, 336-3, 336-4 in FIG. 3) can be directed into the openings of the number of trenches during etching to remove the polymerizing radical material at a bottom of the number of trenches.

The polymerizing radical material may be removed with (via application of) a solvent that is selective for removing (e.g., dissolving) the polymerizing radical material from the memory device while not removing (e.g., leaving) other materials such that those materials remain in the memory device. Such a selective solvent may be selected from water (H₂O), methanol (CH₃OH), ethanol (C₂H₅OH), isomers of propanol (C₃H₇OH) such as n-propanol and isopropanol, n-butanol (C₄H₉OH), among other possible alcohols, and sulfuric acid (H₂SO₄), and combinations thereof, among other possibilities. This removal may leave empty spaces (e.g., voids) in the structure of the memory device that expose a portion of the trenches.

The reactive radical material can be delivered with a high bias power to clear the polymerizing radical material deposited, as was described in association with FIG. 2. The high bias power can lead to a high radical ion energy which can increase an amount of etching of the polymerizing radical material in a narrower trench. In this way, the polymerizing radical material of the narrower trenches can be removed at a higher rate and at an earlier period in time than the polymerizing radical material of the wider trenches. This can expose the portion of the narrower trenches beneath the polymerizing radical material before the portion of the wider trenches beneath the polymerizing radical material.

At block 554, the method 505 can include selectively etching into at least one of the number of trenches below the deposited polymerizing radical material. As an example, an etching material (such as etching material 436-1, 436-2, 436-3, 436-4 in FIG. 4) can be directed into the openings of the number of trenches to etch into a silicate material at a faster rate than a polymer material (e.g., the polymerizing radical material). The etching material can include at least one of chlorine (Cl), hydrogen bromide (HBr), tetrafluoromethane (CF₄), difluoromethane (CH₂F₂), and argon (Ar), where Ar is a carrier gas that directs the etch radical into the etch front. This can result in the polymerizing radical material of the wider trenches being etched more slowly than the silicate material that has been exposed in the narrower trenches.

At a conclusion of the etching, the wider trenches can be a shallower depth than the narrower trenches. This can result in a deeper active fin depth (associated with the active word line of the narrower trench) and a shallower passing fin depth (associated with the passing word line of the wider trench). The deeper the passing fin depth, the more electrons that are available for recombination which improves results of performing a row hammer operation. Further, a shallow passing fin depth improves a distance between passing word lines and also improves performance of a row hammer operation.

The deposition and etching process described above can be repeated a number of times in order to etch the narrower trenches to a depth deeper than the wider trenches until the depth of the narrower trenches reaches a threshold depth. In this way, the effects of micro-loading (an effect where wider trenches are etched to a deeper depth) can be avoided and a trench that is narrower in width can be etched deeper than a trench that is wider.

Subsequent to the method described at blocks 550, 552, and 554, a capacitor material may be deposited into the openings. In addition, a first dielectric material can be formed on the surface of the substrate and sidewalls of the trenches surrounding the capacitor material. Further, a second dielectric material may be formed (e.g., deposited) on the first dielectric material. A buffer material may be formed on the second dielectric material and may be formed around and between a number of capacitors (e.g., capacitors formed in the trenches) as electrical insulation. The dielectric materials and the buffer material may be formed from any respective dielectric materials, conductive materials, and resistive materials and to any width (e.g., thickness) usable in association with formation of an operable capacitor for a semiconductor device.

Formation of the capacitors as described may be utilized in fabrication of a memory device that includes at least one memory cell. Such a memory cell may include at least one such capacitor, as a data storage element. The memory cell also may include at least one access device (e.g., transistor) (not shown) that is, or may be, coupled to the at least one capacitor.

FIG. 6 is a flow diagram of an example method 606 for formation of a capacitor by using a polymerizing radical material in accordance with a number of embodiments of the present disclosure. Unless explicitly stated, elements of methods described herein are not constrained to a particular order or sequence. Additionally, a number of the method embodiments, or elements thereof, described herein may be performed at the same, or at substantially the same, point in time.

At block 660, the method 606 may include depositing a polymerizing radical material in a number of trenches. In some examples, a polymerizing radical material (such as polymerizing radical material 236-1, 236-2, 236-3, 236-4 in FIG. 2) can be directed into openings of trenches to form the polymerizing radical material at a bottom of the trenches. The trenches may have differing width. A wider trench may receive more polymerizing radical material than a narrower trench. The polymerizing radical material can include one or both of CF₄ and CH₂F₂, as an example.

The polymerizing radical material can be deposited with a low bias power to form a deposition layer. This low bias power can lead to a low radical ion energy, which can be used to deposit more polymer in wider openings. As an example, a trench with a wider width can accumulate a greater amount of polymerizing radical material than a trench with a narrower width.

At block 662, the method 606 can include etching a portion of the deposited polymerizing radical material from the number of trenches that are wider in width. In some examples, etching can include using a reactive radical material (such as reactive radical material 336-1, 336-2, 336-3, 336-4 in FIG. 3) to be directed into the openings of the wider number of trenches during etching to remove the polymerizing radical material at a bottom of the wider number of trenches.

The polymerizing radical material may be removed with (via application of) a solvent that is selective for removing (e.g., dissolving) the polymerizing radical material from the memory device while not removing (e.g., leaving) other materials such that those materials remain in the memory device. Such a selective solvent may be selected from water (H₂O), methanol (CH₃OH), ethanol (C₂H₅OH), isomers of propanol (C₃H₇OH) such as n-propanol and isopropanol, n-butanol (C₄H₉OH), among other possible alcohols, and sulfuric acid (H₂SO₄), and combinations thereof, among other possibilities. This removal may leave empty spaces (e.g., voids) in the structure of the memory device that expose a portion of the trenches.

The reactive radical material can be delivered with a high bias power to clear the polymerizing radical material deposited, as was described in association with FIG. 2. The high bias power can lead to a high radical ion energy which can decrease, or slow down, an amount of etching of the polymerizing radical material in these wider trenches. In this way, the polymerizing radical material of the wider trenches can be removed at a lower rate and at a later period in time than the polymerizing radical material of the narrower trenches. This can delay and/or prevent exposure of the portion of the wider trenches beneath the polymerizing radical material.

At block 664, the method 606 can include etching a portion of the deposited polymerizing radical material from the number of trenches that are narrower in width. In some examples, etching can include using a reactive radical material (such as reactive radical material 336-1, 336-2, 336-3, 336-4 in FIG. 3) to be directed into the openings of the narrower number of trenches during etching to remove the polymerizing radical material at a bottom of the narrower number of trenches.

The reactive radical material can be delivered with a high bias power to clear the polymerizing radical material deposited, as was described in association with FIG. 2. The high bias power can lead to a high radical ion energy which can increase an amount of etching of the polymerizing radical material in these narrower trenches. In this way, the polymerizing radical material of the narrower trenches can be removed at a higher rate and at an earlier period in time than the polymerizing radical material of the wider trenches. This can expose the portion of the narrower trenches beneath the polymerizing radical material before the portion of the wider trenches beneath the polymerizing radical material.

At block 666, the method 606 can include selectively etching into a silicate material of the narrower trenches. As an example, an etching material (such as etching material 436-1, 436-2, 436-3, 436-4 in FIG. 4) can be directed into the openings of the narrower trenches to etch into a silicate material at a faster rate than a polymer material (e.g., the polymerizing radical material). The etching material can include at least one of chlorine (Cl), hydrogen bromide (HBr), tetrafluoromethane (CF₄), difluoromethane (CH₂F₂), and argon (Ar), where Ar is a carrier gas that directs the etch radical into the etch front. Such etching materials, such as Cl, HBr, CF₄, CH₂F₂, and Ar, can etch faster into oxide than polymers. This can result in the polymerizing radical material of the wider trenches being etched more slowly than the silicate material that has been exposed in the narrower trenches.

At a conclusion of the etching, the wider trenches can be a shallower depth than the narrower trenches. This can result in a deeper active fin depth (associated with the active word line of the narrower trench) and a shallower passing fin depth (associated with the passing word line of the wider trench). The deeper the passing fin depth, the more electrons that are available for recombination which improves results of performing a row hammer operation. Further, a shallow passing fin depth improves a distance between passing word lines and also improves performance of a row hammer operation.

The deposition and etching process described above can be repeated a number of times in order to etch the narrower trenches to a depth deeper than the wider trenches until the depth of the narrower trenches reaches a threshold depth. In this way, the effects of micro-loading (an effect where wider trenches are etched to a deeper depth) can be avoided and a trench that is narrower in width can be etched deeper than a trench that is wider.

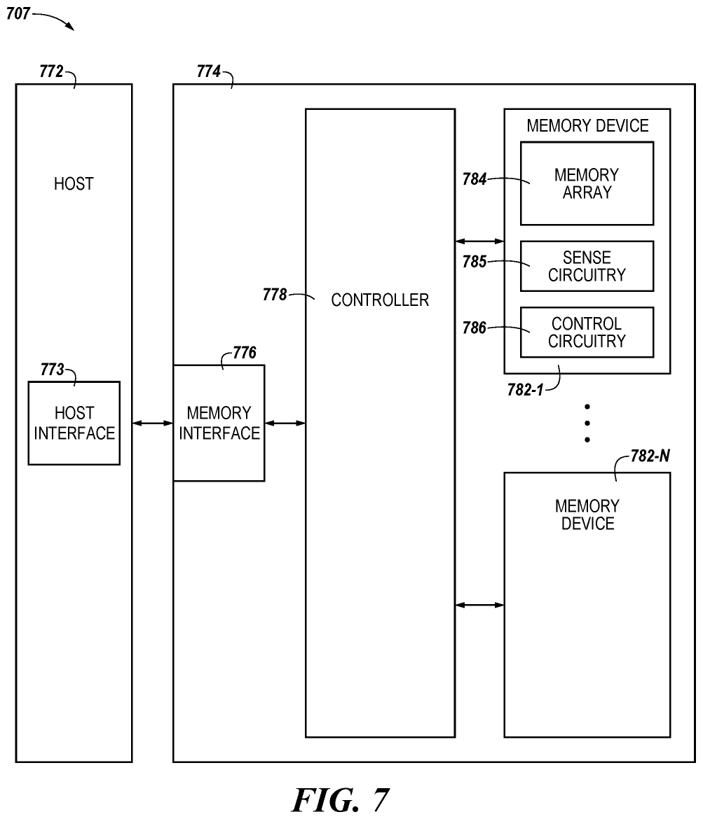

FIG. 7 is a functional block diagram of a computing system 707 including at least one memory system 774 in accordance with one or more embodiments of the present disclosure. Memory system 774 may be, for example, a solid-state drive (SSD).

In the embodiment illustrated in FIG. 7, memory system 774 includes a memory interface 776, a number of memory devices 782-1, . . . , 782-N, and a controller 778 selectably coupled to the memory interface 776 and memory devices 782-1, . . . , 782-N. Memory interface 776 may be used to communicate information between memory system 774 and another device, such as a host 772. Host 772 may include a processor (not shown). As used herein, “a processor” may be a number of processors, such as a parallel processing system, a number of coprocessors, etc. Example hosts may include, or by implemented in, laptop computers, personal computers, digital cameras, digital recording devices and playback devices, mobile telephones, PDAs, memory card readers, interface hubs, and the like. Such a host 772 may be associated with fabrication operations performed on semiconductor devices and/or SSDs using.

In a number of embodiments, host 772 may be associated with (e.g., include or be coupled to) a host interface 773. The host interface 773 may enable input of scaled preferences (e.g., in numerically and/or structurally defined gradients) to define, for example, critical dimensions (CDs) of a final structure or intermediary structures of a memory device (e.g., as shown at 772) and/or an array of memory cells (e.g., as shown at 784) formed thereon to be implemented by a processing apparatus. The scaled preferences may be provided to the host interface 773 via input of a number of preferences stored by the host 772, input of preferences from another storage system (not shown), and/or input of preferences by a user (e.g., a human operator).

Memory interface 776 may be in the form of a standardized physical interface. For example, when memory system 774 is used for information (e.g., data) storage in computing system 707, memory interface 776 may be a serial advanced technology attachment (SATA) interface, a peripheral component interconnect express (PCIe) interface, or a universal serial bus (USB) interface, among other physical connectors and/or interfaces. In general, however, memory interface 776 may provide an interface for passing control, address, information, scaled preferences, and/or other signals between the controller 778 of memory system 774 and a host 772 (e.g., via host interface 773).

Controller 778 may include, for example, firmware and/or control circuitry (e.g., hardware). Controller 778 may be operably coupled to and/or included on the same physical device (e.g., a die) as one or more of the memory devices 782-1, . . . , 782-N. For example, controller 778 may be, or may include, an ASIC as hardware operably coupled to circuitry (e.g., a printed circuit board) including memory interface 776 and memory devices 782-1, . . . , 782-N. Alternatively, controller 778 may be included on a separate physical device that is communicatively coupled to the physical device (e.g., the die) that includes one or more of the memory devices 782-1, . . . , 782-N.

Controller 778 may communicate with memory devices 782-1, . . . , 782-N to direct operations to sense (e.g., read), program (e.g., write), and/or erase information, among other functions and/or operations for management of memory cells. Controller 778 may have circuitry that may include a number of integrated circuits and/or discrete components. In a number of embodiments, the circuitry in controller 778 may include control circuitry for controlling access across memory devices 782-1, . . . , 782-N and/or circuitry for providing a translation layer between host 772 and memory system 774.

Memory devices 782-1, . . . , 782-N may include, for example, a number of memory arrays 784 (e.g., arrays of volatile and/or non-volatile memory cells). For instance, memory devices 782-1, . . . , 782-N may include arrays of memory cells structured to include trenches as described in connection with FIGS. 1-6. As will be appreciated, the memory cells in the memory arrays 784 of memory devices 782-1, . . . , 782-N may be in a RAM architecture (e.g., DRAM, SRAM, SDRAM, FeRAM, MRAM, ReRAM, etc.), a flash architecture (e.g., NAND, NOR, etc.), a three-dimensional (3D) RAM and/or flash memory cell architecture, or some other memory array architecture including pillars and adjacent trenches.

Memory devices 782 may be formed on the same die. A memory device (e.g., memory device 782-1) may include one or more arrays 784 of memory cells formed on the die. A memory device may include sense circuitry 785 and control circuitry 786 associated with one or more arrays 784 formed on the die, or portions thereof. The sense circuitry 785 may be utilized to determine (sense) a particular data value (e.g., 0 or 1) that is stored at a particular memory cell in a row of an array 784. The control circuitry 786 may be utilized to direct the sense circuitry 785 to sense particular data values, in addition to directing storage, erasure, etc., of data values in response to a command from host 772 and/or host interface 773. The command may be sent directly to the control circuitry 786 via the memory interface 776 or to the control circuitry 786 via the controller 778.

The embodiment illustrated in FIG. 7 may include additional circuitry that is not illustrated so as not to obscure embodiments of the present disclosure. For example, memory devices 782 may include address circuitry to latch address signals provided over I/O connectors through I/O circuitry. Address signals may be received and decoded by a row decoder and a column decoder to access a memory array 784. It will be appreciated that the number of address input connectors may depend on the density and/or architecture of memory devices 782 and/or memory arrays 784.

In the above detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure.

It is to be understood that the terminology used herein is for the purpose of describing particular embodiments only and is not intended to be limiting. As used herein, the singular forms “a”, “an”, and “the” include singular and plural referents, unless the context clearly dictates otherwise, as do “a number of”, “at least one”, and “one or more” (e.g., a number of memory arrays may refer to one or more memory arrays), whereas a “plurality of” is intended to refer to more than one of such things. Furthermore, the words “can” and “may” are used throughout this application in a permissive sense (i.e., having the potential to, being able to), not in a mandatory sense (i.e., must). The term “include,” and derivations thereof, means “including, but not limited to”. The terms “coupled” and “coupling” mean to be directly or indirectly connected physically and, unless stated otherwise, can include a wireless connection for access to and/or for movement (transmission) of instructions (e.g., control signals, address signals, etc.) and data, as appropriate to the context.

While example embodiments including various combinations and configurations of semiconductor materials, underlying materials, structural materials, dielectric materials, capacitor materials, substrate materials, silicate materials, nitride materials, buffer materials, etch chemistries, etch processes, solvents, memory devices, memory cells, sidewalls of openings and/or trenches, among other materials and/or components related to formation of a trench using a sacrificial material have been illustrated and described herein, embodiments of the present disclosure are not limited to those combinations explicitly recited herein. Other combinations and configurations of the semiconductor materials, underlying materials, structural materials, dielectric materials, capacitor materials, substrate materials, silicate materials, nitride materials, buffer materials, etch chemistries, etch processes, solvents, memory devices, memory cells, sidewalls of openings and/or trenches related to use of a polymerizing radical material in formation of a trench than those disclosed herein are expressly included within the scope of this disclosure.

Although specific embodiments have been illustrated and described herein, those of ordinary skill in the art will appreciate that an arrangement calculated to achieve the same results may be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

1. A method, comprising:
depositing a polymerizing radical material in a number of trenches formed over a substrate;
etching a portion of the deposited polymerizing radical material from the number of trenches; and
selectively etching into one of the number of trenches below the deposited polymerizing radical material;
wherein the one of the number of trenches is narrower than another of the number of trenches.

2. The method of claim 1, wherein the etching of the portion of the deposited polymerizing material comprises etching using reactive radicals with a high bias power of between 800 to 1600 volts to remove the deposited polymerizing radical material.

3. The method of claim 1, wherein the another of the number of trenches is not selectively etched below the deposited polymerizing radical material.

4. The method of claim 1, wherein the polymerizing radical material comprises one of CF₄ and CH₂F₂.

5. The method of claim 1, wherein the polymerizing radical material is deposited on a silicate material in the number of trenches.

6. The method of claim 1, wherein the deposition of the polymerizing radical material comprises depositing a deeper layer of the polymerizing radical material in a first set of the number of trenches that are wider than a second set of the number of trenches.

7. The method of claim 6, wherein the selective etching comprises selectively etching a silicate material that the polymerizing radical material is deposited on faster than the polymerizing radical material.

8. The method of claim 1, wherein the one of the number of trenches is an active word line trench.

9. The method of claim 1, wherein the another of the number of trenches is a passing word line trench.

10. A method comprising:
depositing a polymerizing radical material in a number of trenches formed over a substrate, wherein the polymerizing radical material is deposited at a higher rate in a first set of the number of trenches than a second set of the number of trenches, wherein each of the first set are wider than the second set;
etching:
a portion of the deposited polymerizing radical material from the first set of the number of trenches; and
the deposited polymerizing radical material from the second set of the number of trenches; and
selectively etching into a silicate material of the second set of the number of trenches that the polymerizing radical material was deposited on.

11. The method of claim 10, wherein a silicate material that the polymerizing radical material is deposited on is exposed in the other of the number of trenches prior to being exposed in the portion of the number of trenches.

12. The method of claim 10, wherein the silicate material comprises one of a borophosphosilicate glass (BPSG) material and a TEOS material.

13. The method of claim 10, further comprising forming a column of capacitor material in the number of trenches.

14. The method of claim 10, wherein the etching is performed using reactive radicals with a high bias power from 800 to 1600 volts to remove all of the deposited polymerizing radical material from the second set of the number of trenches.

15. The method of claim 10, wherein the deposited polymerizing radical material has low bias power of between 100 to 200 volts.

16. The method of claim 10, further comprising subsequent to selectively etching, depositing additional polymerizing radical material in the number of trenches.

17. The method of claim 16, further comprising:
etching the additional polymerizing radical material; and
selectively etching further into the silicate material of the second set of the number of trenches.

18. The method of claim 17, further comprising repeating depositing, etching, and selectively etching until the second set of the number of trenches reach a particular threshold depth.

19. An apparatus, comprising:
a first set of active word line trenches on a substrate; and
a second set of passing word line trenches on the substrate;
wherein the first set of active word line trenches are deeper toward the substrate than the second set of passing word line trenches.

20. The apparatus of claim 19, wherein the first set of active word line trenches are narrower than the second set of passing word line trenches.
